(19) United States
(12) Patent Application Publication
(10) Pub. No.: US 2018/0233427 A1
(43) Pub. Date: Aug. 16, 2018

(54) GRAPHITE HEAT SINK

(71) Applicant: Amazing Cool Technology Corp, Taipei City (TW)

(72) Inventors: Yang-Ming SHIH, Taipei City (TW); Hung-Yun HSU, Taipei City (TW)

(21) Appl. No.: 15/861,678

(22) Filed: Jan. 4, 2018

(30) Foreign Application Priority Data
Feb. 10, 2017 (TW) 106104524

(51) Int. Cl. H01L 23/367; H01L 23/373; F28F 21/02; F28F 3/02

(52) U.S. Cl. CPC H01L 23/3672; H01L 23/373; F28D 2021/0029; F28F 3/02; F28F 21/02

(57) ABSTRACT

A graphite heat sink includes a graphite heat conductive plate and a heat radiation layer. One side of the graphite heat conductive plate is used for absorbing heat from the heat source. The other side of the graphite heat conductive plate is covered by the heat radiation layer. Heat from the heat source is absorbed into the graphite heat conductive plate and then rapidly radiated from the heat radiation layer to dissipate.

### TECHNICAL FIELD

The present invention relates to a heat sink and, in particular, to a graphite heat sink which can dissipate heat by radiation.

### BACKGROUND

Metal heat sinks are the mainstream products in the heat sink market nowadays. Heat from a heat source is conducted to the metal heat sink and then dissipated into a surrounding space by radiation and convection. The metal material used to constitute the metal heat sink is chosen according to its weight, heat transfer properties and price, so the metal heat sink usually consists of aluminum or copper. Aluminum and copper are inexpensive among those metals having good heat transfer efficiency. The thermal conduction coefficient of aluminum is 200 W/(m.K), and the thermal conduction coefficient of copper is 400 W/(m.K). In order to enhance heat dissipation efficiency, fin structures of the metal heat sink are modified for better convection, but since metal materials are limited by their own specific heat dissipation abilities, it is difficult to greatly improve the heat dissipation efficiency of the metal heat sinks.

In view of this, the inventor studied various technologies and created an effective solution in the present disclosure.

### SUMMARY

The present invention provides a heat sink consisting of a graphite material.

The present invention provides a graphite heat sink disposed corresponding to a heat source.

The graphite heat sink includes a graphite heat conductive plate and a heat radiation layer. One side of the graphite heat conductive plate is used for absorbing heat from the heat source. The heat radiation layer covers the other side of the graphite heat conductive plate.

In the graphite heat sink of the present invention, an adhesive layer is sandwiched between the heat radiation layer and the graphite heat conductive plate. The heat radiation layer is in a sheet form and consists of a heat radiation material. The heat radiation layer consists of a graphene sheet. The heat radiation layer can consist of a single graphene sheet. Alternatively, the heat radiation layer can consist of a plurality of graphene sheets connected to each other.

In the graphite heat sink of the present invention, the heat radiation layer includes a fixing structure covering the graphite heat conductive plate and includes a plurality of heat radiation particles scattered and embedded in the fixing structure. The heat radiation particle is a graphene fragment. The heat radiation particle is a nano-carbon ball. The fixing structure consists of a cured gel material.

The graphite heat sink utilizes a graphite heat conductive plate to absorb heat from the heat source and rapidly transfer and spread the heat. The heat is then dissipated by the heat radiation layer by radiation. Compared to conventional metal heat sinks, the present invention has superior heat dissipation efficiency.

### BRIEF DESCRIPTION OF THE DRAWINGS

The disclosure will become more fully understood from the detailed description and the drawings given herein below for illustration only, and thus does not limit the disclosure, wherein:

FIG. 1 is a schematic view illustrating a graphite heat sink according to the first embodiment of the present invention;

FIG. 2 is a schematic view illustrating a graphite heat sink according to the second embodiment of the present invention;

FIG. 3 is a schematic view illustrating a graphite heat sink according to the third embodiment of the present invention; and

FIG. 4 is a schematic view of another configuration for the graphite heat sink.

### DETAILED DESCRIPTION

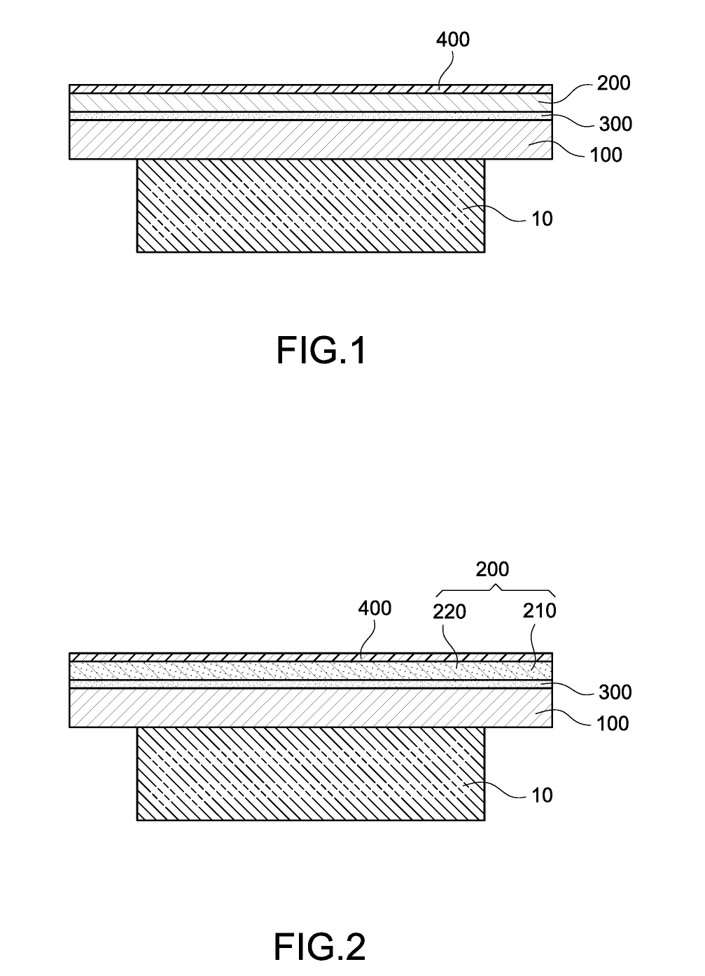

Please refer to FIG. 1 illustrating a graphite heat sink according to the first embodiment of the present invention. The graphite heat sink is disposed corresponding to a heat source 10 for dissipating heat by radiation. The heat source 10 is, for example, an integrated circuit (IC) chip, a circuit board, or other heat source element. In the present embodiment, the graphite heat sink includes a graphite heat conductive plate 100 and a heat radiation layer 200.

The graphite heat conductive plate 100 is a graphite sheet. Graphite is a multi-layered structure consisting of carbon atoms arranged in a hexagonal lattice. The graphite is natural graphite or artificial graphite. The thermal conduction coefficient of natural graphite is 600 W/(m.K) or higher, and the thermal conduction coefficient of artificial graphite is 1500 W/(m.K) or higher. One side of the graphite heat conductive plate 100 is used for absorbing heat from the heat source 10. The heat is then conducted to every portion of the graphite heat conductive plate 100.

The heat radiation layer 200 covers the other side of the graphite heat conductive plate 100. In the present embodiment, the heat radiation layer 200 is in a sheet form and consists of a heat radiation material. The heat radiation layer 200 preferably consists of a graphene sheet. Graphene is a single layer of carbon atoms arranged in a hexagonal lattice. The heat radiation layer 200 can consist of a single graphene sheet. Alternatively, the heat radiation layer 200 can consist of a plurality of graphene sheets connected to each other. An adhesive layer 300 is sandwiched between the heat radiation layer 200 and the graphite heat conductive plate 100. The heat radiation layer 200 is adhered and fixed to the graphite heat conductive plate 100 by means of the adhesive layer 300. The heat radiation layer 200 is covered by a protection layer 400. The protection layer 400 has electrical insulation properties and can allow heat to radiate therethrough. The protection layer 400 preferably consists of PET (polyethylene terephthalate). It is difficult to make the graphene sheet directly cover the graphite heat conductive plate 100. Therefore, the graphene sheet is preferably formed on the adhesive layer 300 or the protection layer 400 first, and then is adhered to the graphite heat conductive plate 100.

Please refer to FIG. 2 illustrating a graphite heat sink according to the second embodiment of the present invention. The graphite heat sink is disposed corresponding to a heat source 10 for dissipating heat by radiation. The heat source 10 is, for example, an integrated circuit (IC) chip. In the present embodiment, the graphite heat sink includes a graphite heat conductive plate 100 and a heat radiation layer 200.

The graphite heat conductive plate 100 is a graphite sheet consisting of natural graphite or artificial graphite. One side of the graphite heat conductive plate 100 is used for absorbing heat generated by the heat source 10, and then the heat is transferred to every portion of the graphite heat conductive plate 100.

The heat radiation layer 200 covers the other side of the graphite heat conductive plate 100. In the present embodiment, an adhesive layer 300 is sandwiched between the heat radiation layer 200 and the graphite heat conductive plate 100. The heat radiation layer 200 is adhered and fixed to the graphite heat conductive plate 100 by means of the adhesive layer 300. The heat radiation layer 200 is covered by a protection layer 400. The protection layer 400 has electrical insulation properties and can allow heat to radiate therethrough. The protection layer 400 preferably consists of polyethylene terephthalate (PET).

The heat radiation layer 200 includes a fixing structure 210 covering the graphite heat conductive plate 100 and includes a plurality of heat radiation particles 220 scattered and embedded in the fixing structure 210. The fixing structure 210 consists of a cured gel material (e.g. a gel or paint). The fixing structure 210 preferably consists of an electric insulation gel material to prevent the heat source from being damaged by electricity. The heat radiation particles 220 can be graphene fragments, and the heat radiation particles 220 can also be nano-carbon balls. The nano-carbon ball consists of carbon atoms arranged in a ball shape.

Before the gel material is cured, the heat radiation particles 220 are mixed with the gel material, so that the heat radiation particles 220 are dispersed evenly. Then, the mixture of the heat radiation particles 220 and the gel material covers the adhesive layer 300 by spraying, coating, or printing. After that, the mixture is adhered to the graphite heat conductive plate 100 by means of the adhesive layer 300. In an alternative production method, the mixture of the heat radiation particles 220 and the unsolidified gel material covers the protection layer 400 by spraying, coating or printing. Then, the adhesive layer 300 covers the heat radiation layer 200 by spraying, coating or printing. After that, the mixture is adhered to the graphite heat conductive plate 100 by means of the adhesive layer 300.

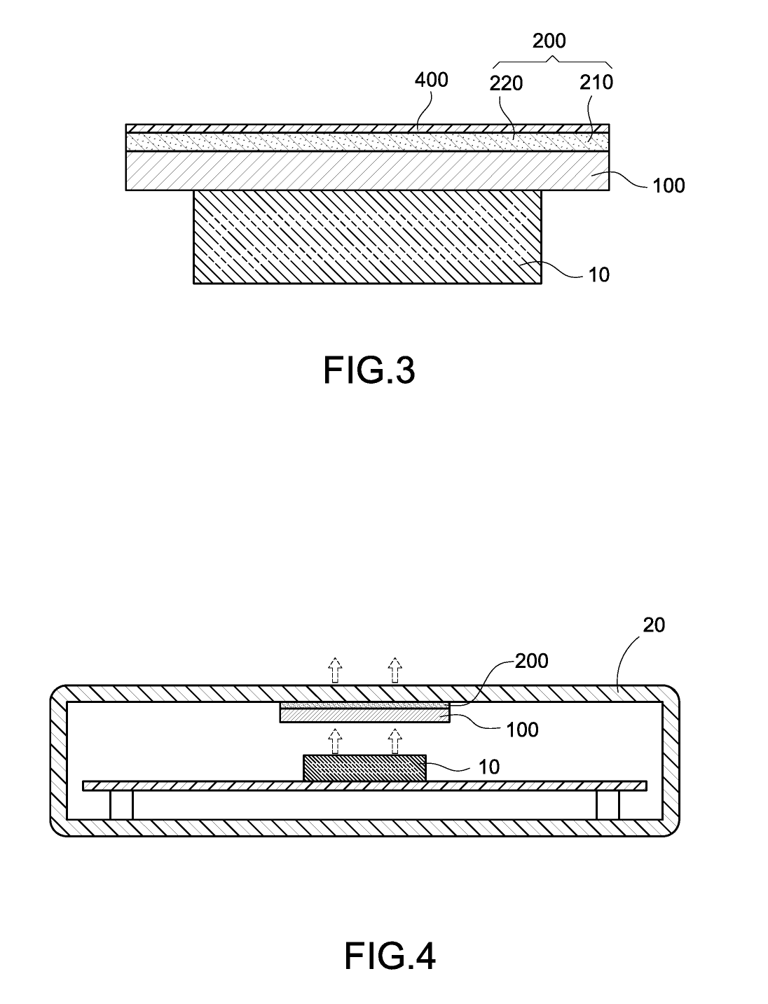

Please refer to FIG. 3 illustrating a graphite heat sink according to the third embodiment of the present invention. The graphite heat sink is disposed corresponding to a heat source 10 for dissipating heat by radiation. The heat source 10 is, for example, an IC chip. In the present embodiment, the graphite heat sink includes a graphite heat conductive plate 100 and a heat radiation layer 200.

The graphite heat conductive plate 100 is a graphite sheet consisting of natural graphite or artificial graphite. One side of the graphite heat conductive plate 100 is used for absorbing heat from the heat source 10, and then the heat is conducted and spread to every portion of the graphite heat conductive plate 100.

The heat radiation layer 200 covers the other side of the graphite heat conductive plate 100. In the present embodiment, the heat radiation layer 200 includes a fixing structure 210 covering the graphite heat conductive plate 100 and includes a plurality of heat radiation particles 220 scattered and embedded inside the fixing structure 210. The fixing structure 210 consists of a cured gel material (e.g. a gel or plastic). The fixing structure 210 preferably consists of an electrical insulation gel material to prevent the flow of electricity to the heat source to damage the same. The heat radiation particles 220 can be graphene fragments. Alternatively, the heat radiation particles 220 can be nano-carbon balls, and the nano-carbon ball consists of carbon atoms arranged in a ball shape. The heat radiation layer 200 is covered by a protection layer 400. The protection layer 400 has electrical insulation property and can allow heat to radiate therethrough. The protection layer 400 preferably consists of PET (polyethylene terephthalate).

The heat radiation particles 220 are first mixed with the unsolidified gel material, so that the heat radiation particles 220 can be dispersed evenly. Then, the mixture of the heat radiation particles 220 and the gel material covers the graphite heat conductive plate 100 by spraying, coating, or printing.

In the above-mentioned embodiments, the graphite heat sink is adhered to the heat source 10, so that the heat generated by the heat source 10 can be conducted to the graphite heat conductive plate 100 in contact with the heat source 10; however, the present invention is not limited in this regard. Referring to FIG. 4, the graphite heat sink can also be adhered to an inner surface of a housing 20 of an electronic device. Preferably, the heat radiation layer 200 is adhered to a non-mental portion of the housing 20 of the electronic device. The graphite heat sink 100 is preferably disposed corresponding to the heat source 10 of the electronic device, but does not contact the heat source 10. The heat generated by the heat source 10 is transferred to the graphite heat sink 100 by radiation. The heat radiation layer 200 can dissipate the heat by radiation, i.e. the heat is radiated to penetrate through the non-mental portion of the housing 20 and to be thereby expelled to the outside of the electronic device.

In summary, the graphite heat sink utilizes the graphite heat conductive plate 100 to absorb the heat from the heat source 10 and rapidly transfer and spread the heat by conduction. Then, the heat is dissipated by the heat radiation layer 200 by radiation. Compared to the conventional metal heat sinks, the present invention has superior heat dissipation efficiency, and allows heat to be dissipated through a plastic structure which is an obstacle to heat dissipation for conventional metal heat sinks. Furthermore, the present invention is light and has a small size to be adapted to various uses, has low production costs, and facilitates easy transport and installation.

It is to be understood that the above descriptions are merely the preferable embodiments of the present invention and are not intended to limit the scope of the present invention. Equivalent changes and modifications made in the spirit of the present invention are regarded as falling within the scope of the present invention.

What is claimed is:

1. A graphite heat sink, disposed corresponding to a heat source, comprising:
a graphite heat conductive plate, one side of the graphite heat conductive plate being used for absorbing heat from the heat source; and
a heat radiation layer, the heat radiation layer covering the other side of the graphite heat conductive plate.

2. The graphite heat sink according to claim 1, wherein an adhesive layer is sandwiched between the heat radiation layer and the graphite heat conductive plate.

3. The graphite heat sink according to claim 2, wherein the heat radiation layer is in a sheet form and consists of a heat radiation material.

4. The graphite heat sink according to claim 3, wherein the heat radiation layer consists of a graphene sheet.

5. The graphite heat sink according to claim 4, wherein the heat radiation layer consists of a single graphene sheet.

6. The graphite heat sink according to claim 4, wherein the heat radiation layer consists of a plurality of graphene sheets connected to each other.

7. The graphite heat sink according to claim 1, wherein the heat radiation layer includes a fixing structure covering the graphite heat conductive plate and includes a plurality of heat radiation particles scattered and embedded in the fixing structure.

8. The graphite heat sink according to claim 7, wherein the heat radiation particle is a graphene fragment.

9. The graphite heat sink according to claim 7, wherein the heat radiation particle is a nano-carbon ball.

10. The graphite heat sink according to claim 7, wherein the fixing structure consists of a cured gel material.

11. The graphite heat sink according to claim 2, wherein the heat radiation layer includes a fixing structure covering the graphite heat conductive plate and includes a plurality of heat radiation particles scattered and embedded in the fixing structure.

12. The graphite heat sink according to claim 11, wherein the heat radiation particle is a graphene fragment.

13. The graphite heat sink according to claim 11, wherein the heat radiation particle is a nano-carbon ball.

14. The graphite heat sink according to claim 11, wherein the fixing structure consists of a cured gel material.
